(19) United States
(12) Patent Application Publication
(10) Pub. No.: US 2014/0196773 A1
(43) Pub. Date: Jul. 17, 2014

(54) MULTI-JUNCTION III-V SOLAR CELL

(71) Applicant: INTERNATIONAL BUSINESS MACHINES CORP, Armonk, NY (US)

(72) Inventors: Stephen W. Bedell, Wappingers Falls, NY (US); Bahman Hekmatshoartabari, White Plains, NY (US); Devendra K. Sadana, Pleasantville, NY (US); Ghavam G. Shahidi, Pound Ridge, NY (US); Davood Shahrjerdi, White Plains, NY (US)

(73) Assignee: INTERNATIONAL BUSINESS MACHINES CORPORATION, Armonk, NY (US)

(21) Appl. No.: 13/738,989

(22) Filed: Jan. 11, 2013

(51) Int. Cl. H01L 31/0725; H01L 31/18

(52) U.S. Cl. CPC H01L 31/0725; H01L 31/18
USPC 136/255; 438/94

(57) ABSTRACT

A multi junction solar cell structure includes a top photovoltaic cell including III-V semiconductor materials and a silicon-based bottom photovoltaic cell. A thin, germanium-rich silicon germanium buffer layer is provided between the top and bottom cells. Fabrication techniques for producing multi junction III-V solar cell structures, lattice-matched or pseudomorphic to germanium, on silicon substrates is further provided wherein silicon serves as the bottom cell. The open circuit voltage of the silicon cell may be enhanced by localized back surface field structures, localized back contacts, or amorphous silicon-based heterojunction back contacts.

### FIELD

The present disclosure relates to the physical sciences, and, more particularly, to photovoltaic structures comprising III-V absorber materials and the fabrication of such structures.

### BACKGROUND

Multi junction III-V solar cell structures are in general grown on germanium (Ge) substrates due to the nearly identical lattice constant of Ge and some III-V semiconductor materials such as InGaAs (with one percent (1%) In content) and InGaP₂. As a result, Ge substrates are also utilized as a third junction in such structures due to its smaller bandgap than those of the InGaAs and InGaP₂. Although the use of Ge as the bottom cell tends to increase the total efficiency of the conventional triple junction solar cell structures, this solar cell structure is not optimum from the standpoint of bandgap engineering for maximizing short circuit current. To mitigate this problem, the use of upright metamorphic structures has been proposed, wherein the bandgap of the middle InGaAs cell has been further reduced by increasing the indium content. Nonetheless, from the standpoint of bandgap engineering it is desirable to employ a material with a bandgap of ˜0.9-1.1 eV as the bottom cell. A prominent example of such structure is the inverted metamorphic solar cell. The inverted metamorphic solar cell structures offer higher conversion efficiency than those of conventional triple junction and upright metamorphic solar cells. However, the inverted metamorphic solar cells are costly due to special growth process to realize a III-V junction with a bandgap of ˜1.0 eV as well as additional fabrication process required to separate the solar cell structure from the host substrate.

Referring to FIG. 6, a conventional double junction solar cell structure 10 is shown. The structure includes a top cell and a bottom cell separated by a tunnel junction 34A, 34B. The bottom cell is formed on a buffer layer 22, 24 which is, in turn, formed on a p+ silicon handle 20. The buffer layer includes a p+ thick (1-3μm) graded SiₓGe₁₋ₓ layer 22 adjoining the handle layer 20 and a p+ (In)GaAs layer 24. The bottom cell comprises III-V semiconductor materials. In this specific example, the base layer 28 of the bottom cell is p-(In)GaAs and the emitter layer 30 is n+ (In)GaAs. A back surface field (BSF) layer of the bottom cell adjoins the buffer layer. A window layer 32 is formed on the emitter layer 30. The top cell includes a p-InGaP base 38, a n+ InGaP emitter layer 40, a BSF layer 36 and a window layer 42. An anti-reflective coating (ARC) 44 adjoins the window layer. Contact layers 48, 50 are provided at the top and bottom of the structure 100. The top contact layer 48 adjoins a highly doped n+ (In)GaAs layer 46 while the bottom contact layer 50 adjoins the handle layer 20. In this structure 10, the silicon layer 20 is not a part of a photovoltaic cell and functions only as a carrier.

### SUMMARY

Principles of the present disclosure provide a multi junction III-V solar cell structure and techniques for manufacturing of multi junction solar cell structures that include both III-V and silicon absorbers.

A solar cell structure in accordance with an exemplary embodiment includes a top photovoltaic cell having a bandgap between 1.8-2.1eV, the top photovoltaic cell including a first base layer and a first emitter layer adjoining the first base layer, the first base and emitter layers each being comprised of a III-V semiconductor material. The solar cell structure further includes a bottom photovoltaic cell including a second base layer and a second emitter layer adjoining the second base layer, the second base and emitter layers each being comprised of silicon. A buffer layer is between the top and bottom photovoltaic cells, the buffer layer comprising silicon and germanium and having a germanium-rich portion, the top photovoltaic cell being lattice matched or pseudomorphic to the germanium-rich portion of the buffer layer. A tunnel junction is between the top photovoltaic cell and the buffer layer.

A second exemplary structure includes a top photovoltaic cell having a bandgap between 1.8-2.1 eV, the top photovoltaic cell including a first base layer and a first emitter layer adjoining the first base layer, the first base and emitter layers each being comprised of a III-V semiconductor material. The second exemplary structure further includes a bottom photovoltaic cell including a crystalline silicon second base layer and a second emitter layer adjoining the second base layer. A first buffer layer having a thickness of less than 0.5 μm is between the top and bottom photovoltaic cells of the structure, the first buffer layer including a silicon germanium portion adjoining the bottom photovoltaic cell and a germanium-rich portion comprising at least ninety percent germanium, the top photovoltaic cell being lattice-matched or pseudomorphic to the germanium-rich portion of the first buffer layer. A tunnel junction is between the first buffer layer and the top photovoltaic cell and a second buffer layer is between the first buffer layer and the tunnel junction. The second buffer is effective for avoiding antiphase boundary defects.

An exemplary fabrication method includes obtaining a bottom photovoltaic structure comprising a crystalline silicon base and an emitter layer comprising silicon on the base, forming a first buffer layer on the bottom photovoltaic structure, the first buffer layer including a first portion comprising silicon and germanium and a second, germanium-rich portion having a substantially greater percentage of germanium than the first portion, forming a tunnel junction over the first buffer layer, and forming a top photovoltaic cell having a bandgap between 1.8-2.1 eV over the tunnel junction and lattice matched or pseudomorphic to the germanium-rich portion of the buffer layer. The top photovoltaic cell includes a first base layer and a first emitter layer adjoining the first base layer, the first base and emitter layers each being comprised of a III-V semiconductor material.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Solar cell structures as disclosed herein can provide substantial beneficial technical effects. For example, one or more embodiments may provide one or more of the following advantages:

High open circuit voltage (V_{oc})

High solar cell efficiency (η)

Less expensive compared to the conventional III-V structures.

These and other features and advantages will become apparent from the following detailed description of illustrative embodiments thereof, which is to be read in connection with the accompanying drawings.

### BRIEF DESCRIPTION OF THE DRAWINGS

FIG. 1 is a schematic illustration of a multi junction solar cell structure having a silicon-based bottom cell and a group III-V-based top cell;

FIG. 2 is a schematic illustration of a multi junction solar cell structure having a localized back surface field structure; FIG. 3 is a schematic illustration of a second embodiment of a multi junction solar cell structure having a localized back surface field structure;

FIG. 4 is a schematic illustration of a multi junction solar cell structure having a heterojunction hydrated amorphous silicon based back surface field structure;

FIG. 5 is a schematic illustration of a second embodiment of a multi junction solar cell structure having a heterojunction hydrated amorphous silicon based back surface field structure, and

FIG. 6 is a schematic illustration of a prior art double junction solar cell structure on a silicon substrate.

### DETAILED DESCRIPTION

Multi junction III-V solar cell structures, lattice-matched or pseudomorphic to germanium, on a compliant silicon substrate are disclosed wherein silicon serves as a bottom cell in such structures. The growth of III-V based cells on silicon is advantageous for a number of reasons, including (1) abundance of Si substrates, (2) lower cost of silicon compared to that of germanium and III-V semiconductor materials, (3) mechanical stability, and (4) optimum bandgap of silicon for making high-efficiency tandem junction solar cells. The lattice mismatch between silicon and III-V semiconductor materials is an impediment in realizing tandem III-V solar cells on silicon, wherein silicon serves as the bottom junction. Due to the challenging nature of III-V semiconductor material growth directly on silicon on large areas, as opposed to small patterned areas, researchers have attempted to utilize graded SiGe buffer layers as a template for growing III-Vs on silicon substrates. A relatively thick SiGe buffer layer is, in principle, grown to gradually relax the strain and grow Ge-rich layers. The smaller bandgap of SiGe than that of silicon, however, negates the possibility of using the silicon substrate as a bottom cell due to strong absorption of solar spectrum in a thick SiGe buffer layer and subsequent annihilation of photo-generated carriers in the highly defective SiGe buffer layer. In accordance with the present disclosure, multi junction III-V solar cell structures are fabricated in such a manner that the silicon substrates are used to form bottom cells.

Exemplary solar cell structures disclosed herein include a multi junction III-V solar cell structure on a compliant silicon substrate wherein silicon serves as the bottom photovoltaic cell. Compliant silicon substrates are engineered to accommodate the lattice mismatch between the silicon substrate and a III-V layer thereon. In the exemplary structures, which are discussed in further detail below, a relatively thin, germanium-rich silicon germanium (SiGe) buffer layer is grown on crystalline silicon (c-Si). The strain relaxation depends on the thickness of the Ge-rich SiGe layer (Ge layer). The thickness of the buffer layer in the exemplary structures is below 1 μm and more preferably below 0.5 μm. The preferred thickness of this layer 64 is <0.25 μm. The buffer layer 64 in exemplary embodiments is grown using a rapid thermal chemical vapor deposition (RTCVD) process. Silane and germane are employed in the process to grow SiGe on the silicon-based bottom cell. The portion of the resulting buffer layer 64 adjoining the bottom cell contains about twenty to fifty percent germanium and has a thickness of less than one hundred nanometers, for example about ten to twenty nanometers. The germanium content of the remaining portion of the buffer layer 64 is substantially higher than the portion adjoining the bottom cell, preferably ninety percent or more germanium, and one hundred percent (100%) germanium (atomic percent) in some embodiments. In exemplary embodiments including p-type base layers 60, 38, n-type dopants such as phosphorus or arsenic are included in the buffer layer 64. This remaining, germanium-rich portion of the buffer layer 64 has a thickness range of 50 nm-1 μm in exemplary embodiments, a thickness range between 50-300 nm being employed in some embodiments. Lattice matching of the III-V top cell to the germanium-rich portion of the buffer layer, which may comprise one hundred percent germanium in some embodiments, can thereby be accomplished to a satisfactory extent wherein the III-V layers are pseudomorphic to the compliant substrate on which they are grown. Alternatively, the buffer layer 64 may be grown using an ultra high vacuum chemical vapor deposition process employing silane and germane at a process temperature between 300-600° C.

An advantage of solar cell structures as disclosed herein over conventional structures having germanium-based bottom photovoltaic cells is the higher open circuit voltage of silicon cells compared to that of germanium cells. The open circuit voltage of the silicon cell can be further enhanced by the addition of advanced features such as a localized back-surface field, a localized back contact, and a-Si:H based heterojunction back contact. Additionally, the silicon-based bottom cell can be thinner than fifty microns (50 μm) since nearly fifty percent (50%) of the spectrum will be absorbed by the top III-V cell.

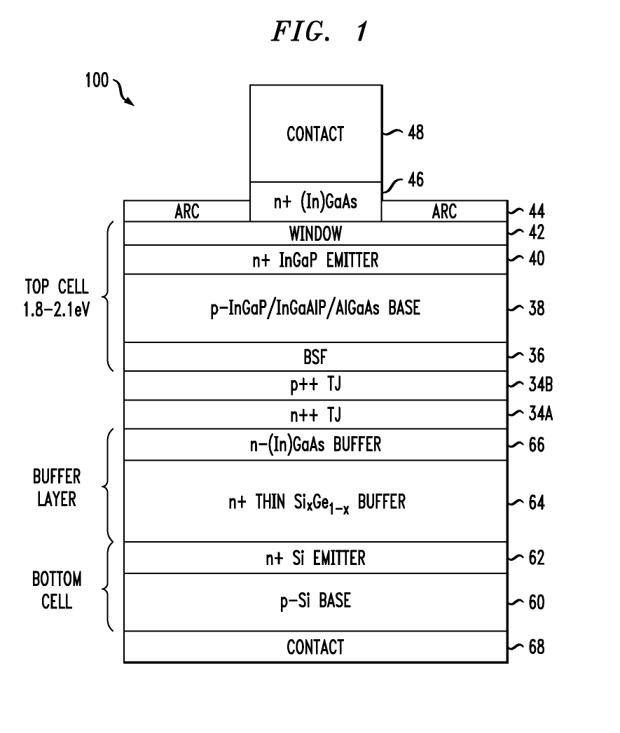

FIG. 1 is a schematic illustration of a monolithic, multi junction solar cell structure 100 in accordance with a first exemplary embodiment. The structure 100 includes a bottom cell comprising a light absorbing, silicon base layer 60 and a silicon emitter layer 62. A contact layer 68 adjoins and is in electrical communication with the base layer 60. In this exemplary embodiment, the base layer 60 comprises p-Si and the emitter layer 62 is a highly doped n+ Si layer. In this exemplary embodiment, the silicon is crystalline and the n+ emitter layer can be formed via diffusion, implantation or epitaxy. Alternatively, the n+ SiGe bottom portion of the buffer layer 64 may be employed as an emitter layer. The silicon base can be fabricated from a thin wafer. Alternatively, the entire structure can be spalled from a relatively thick silicon substrate following growth of the III-V structure thereon. Controlled spalling techniques are disclosed, for example, in U.S. Publication Nos. 2010/0307572 and 2011/0048517, both of which are incorporated by reference herein. The contact layer 68 may be comprised of aluminum, aluminum paste, silver, or silver paste in exemplary embodiments of the disclosed structure 100 as well as other structures 200, 300, 400 and 500 discussed in further detail below. If controlled spalling is employed in the fabrication process, the contact layer 68 would be formed following the controlled spalling procedure.

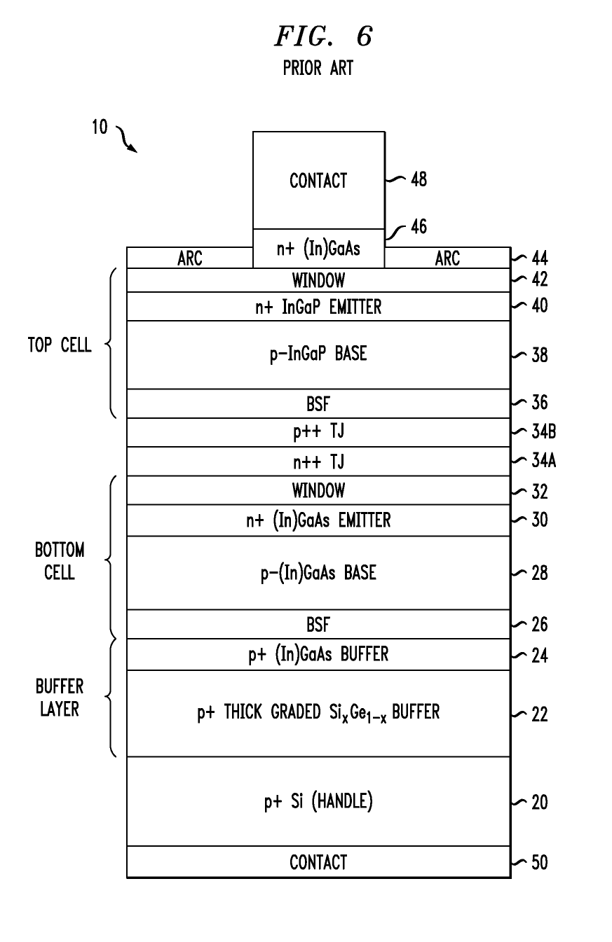

The top photovoltaic cell in the exemplary embodiment of FIG. 1 is the same as that shown in FIG. 6 discussed above. The same reference numerals are accordingly employed to designate layers common to those found in FIG. 6. The top cell is comprised of III-V semiconductor materials grown pseudomorphically or lattice matched to the underlying substrate. In exemplary embodiments, the base layer 38 is comprised of p-InGaP, p-InGaAlP, or p-AlGaAs. The emitter layer 40 in this exemplary embodiment is n+ InGaP and may be disordered. The bandgap of the base material is 1.8-2.1 eV in the embodiments of the exemplary structure 100. The bandgap of the emitter layer 40 is in the same range in the exemplary embodiment. Those of skill in the art will appreciate that the base layers 38, 60 of the structure 100 may alternatively be n-type, in which case p-type emitter layers are formed thereon.

The BSF layer 36 may be comprised of materials such as InGaP, AlGaAs, or InGaAlP, or a combination of thereof in the exemplary embodiment. In one exemplary embodiment, the BSF layer is formed from Zn:In_{0.5}Ga_{0.5}P. Suitable materials for the window layer 42 include InAlP, and InGaAlP (e.g. In_{0.5}(Ga₁₋ₓAlₓ)_{0.5}P. In the latter example, aluminum is provided in a 20-50% ratio with respect to gallium.

The top and bottom cells of the structure 100 are separated by highly doped n++ and p++ layers 34A, 34B comprising the tunnel junction and a buffer layer 64, 66. The buffer layer includes the n+ SiₓGe₁₋ₓ layer 64 as discussed above that adjoins the n+ silicon emitter layer of the bottom cell and a n-(In)GaAs layer 66 that interfaces with the tunnel junction. The designation (In) indicates that the indium content is low, for example between one and three percent. The tunnel junction adjoins the BSF layer 36 of the top cell. The n-(In)GaAs layer 66 (alternatively an (In)GaP layer) is provided to avoid antiphase boundary (APB) defects. In some exemplary embodiments where the adjoining portion of the buffer layer 64 is one hundred percent germanium, the indium content of the n-(In)GaAs layer 66 is one percent. The tunnel junction can be comprised of GaAs, InAlP, AlGaS or InGaP in one or more exemplary embodiments. Doping of the n-type layers of the tunnel junction and III-V cell can be effected using silicon (Si) or tellurium (Te), the latter being preferred for forming the tunnel junction. The p-type layers can be formed using carbon (C) or zinc (Zn) dopants, with carbon preferred in the tunnel junction.

The overall thickness of the III-V top cell of the exemplary solar cell structure 100 shown in FIG. 1 is less than 1.5 μm while the maximum thickness of the base layer thereof is about 1 μm. The thicknesses are considered exemplary as opposed to limiting. The short circuit current J_{sc} of the structure 100 is limited by the III-V top cell. In this exemplary embodiment, the short circuit current of the stand-alone silicon-based bottom cell is about 40 mA/cm² while the short circuit current of the tandem structure is about 14-15 mA/cm². Based on the first-order calculations, the open circuit voltage V_{oc} of the exemplary structure 100 is estimated to be about 2V, the fill factor FF is estimated to be about 85%, and the energy conversion efficiency (η) is therefore deduced to be about 25.5%.

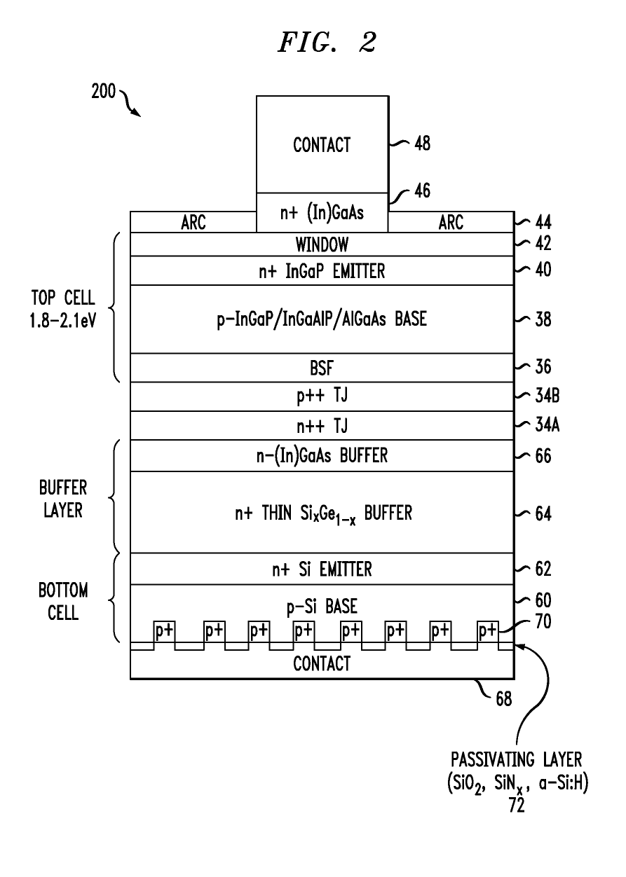

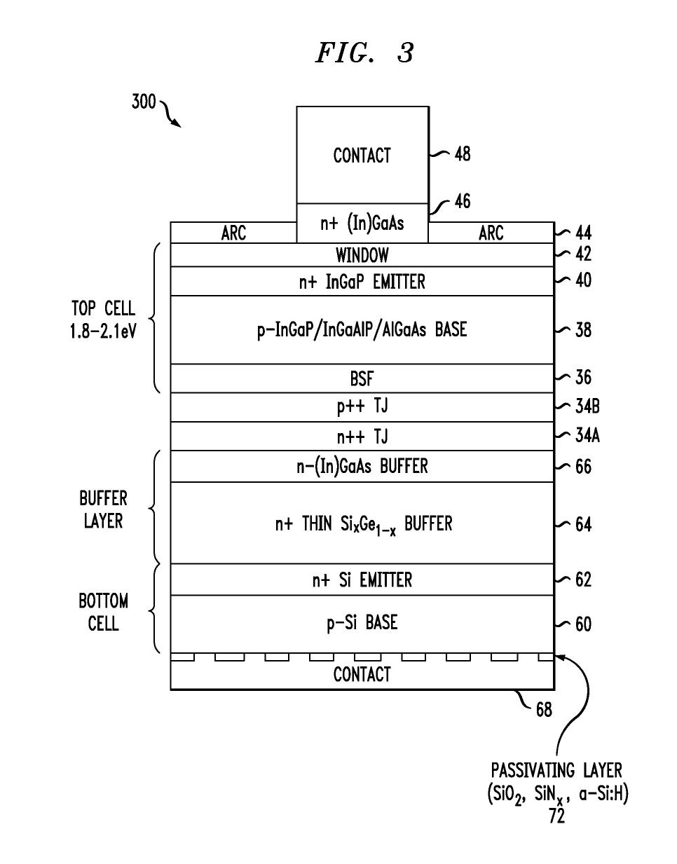

FIG. 2 shows a second exemplary embodiment of a multi junction solar cell structure 200 that includes a localized back surface field structure for increasing V_{oc} and the resulting cell efficiency. The top and bottom cells are otherwise substantially the same as those discussed with respect to FIGS. 1 and 6 and the elements thereof are identified by the same reference numerals. In this embodiment, the p-type silicon base 60 of the bottom cell includes highly doped regions 70, designated as p+ regions in FIG. 2. These regions adjoin corresponding regions of the contact layer. A passivating layer 72 is provided between the contact layer and the base 60. The doped regions 70 are formed through diffusion or implantation of dopants (boron and aluminum for p+ regions, alternatively phosphorus for n+ regions) in the exemplary embodiment. The passivation layer 72 is formed via thermal oxidation or PECVD deposition of nitride and hydrogenated amorphous silicon (a-Si:H) in some embodiments. Alternatively, passivating layers such as Al₂O₃ can be employed. The passivating layer 72 is patterned to facilitate formation of the doped regions 70. Subsequent deposition of the contact layer 68 on the patterned passivating layer results in contact between the contact layer and the localized doped regions 70 within the silicon base 60.

FIG. 3 shows a structure 300 similar to that shown in FIG. 1 as indicated by the use of similar reference numerals. The structure includes a localized back contact (LBC) structure. The contact layer includes discrete regions that contact the bottom surface of the bottom cell. A passivating layer 72 is provided between these discrete regions and adjoins the bottom surface of the silicon base 60. The passivating layer 72 is patterned prior to formation of the contact layer 68 to enable the localized contact with the silicon base 60 depicted in the schematic illustration.

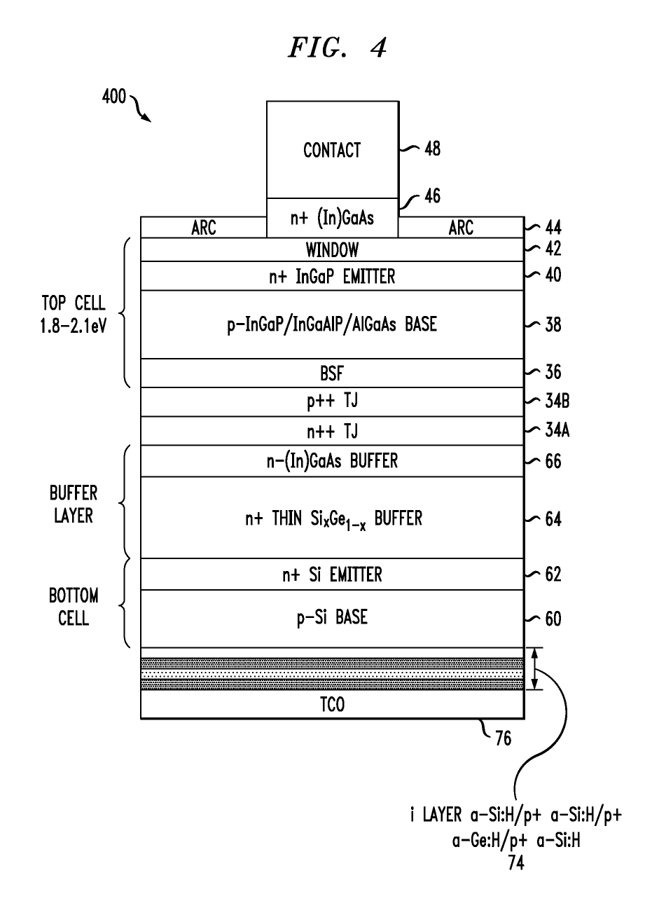

FIG. 4 shows a further exemplary multi junction solar cell structure 400 having top and bottom cells separated by a SiₓGe₁₋ₓ buffer layer and a highly doped tunnel junction 34A, 34B. The top and bottom cells are the same as those described above with respect to FIGS. 1-3, namely a III-V top cell and a silicon-based bottom cell. The structure includes a heterojunction a-Si:H (hydrogenated amorphous silicon) based back surface field layer 74. In the exemplary structure, the back surface field (BSF) layer includes four layers, namely an intrinsic layer of a-Si:H, a p+ a-Si:H layer, a p+ a-Ge:H layer, and a p+ a-Si:H layer. The intrinsic layer adjoins the base layer 60. A transparent conductive oxide layer 76 adjoins the back surface field layer 74.

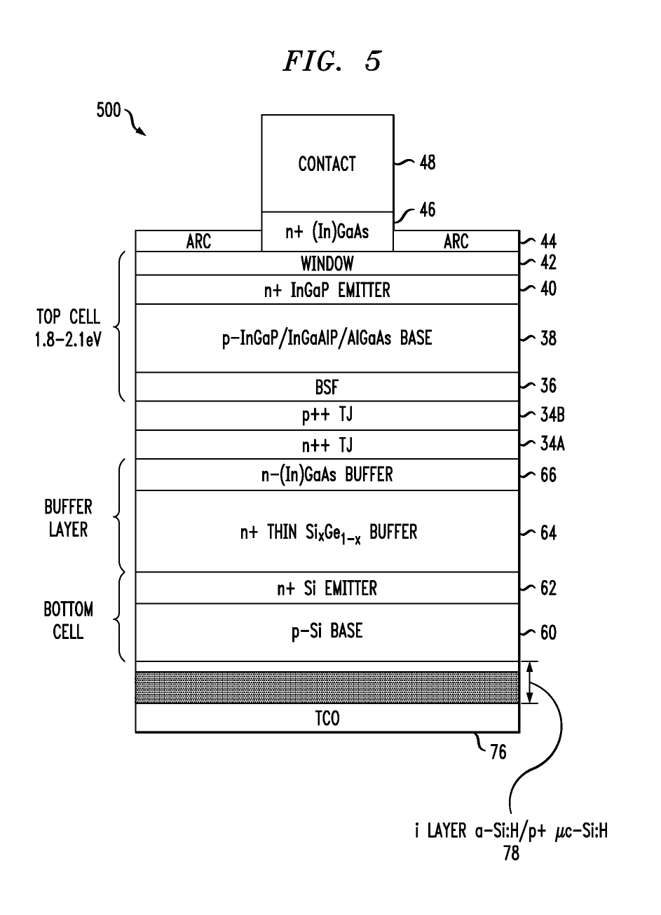

FIG. 5 shows a further exemplary embodiment of a multi junction solar cell structure 500 having top and bottom cells separated by a SiₓGe₁₋ₓ buffer layer and a highly doped tunnel junction 34A, 34B. The top and bottom cells are the same as those described above with respect to FIGS. 1-4. The structure 500 includes a heterojunction a-Si:H based back surface field layer 78 adjoining the base layer 60 of the bottom, silicon-based cell. In this exemplary embodiment, the BSF layer 78 includes an i-layer of a-Si:H adjoining the base layer 60 and a μc-Si:H layer that adjoins the TCO layer 76.

Given the discussion thus far and with reference to the exemplary embodiments discussed above and the drawings, it will be appreciated that, in general terms, an exemplary multi junction solar cell structure is provided. The structure includes a top photovoltaic cell including a first base layer 38 and a first emitter layer 40 adjoining the first base layer, the first base and emitter layers each being comprised of a III-V semiconductor material. The structure further includes a bottom photovoltaic cell including a second base layer 60 and a second emitter layer 62 adjoining the second base layer, the second base and emitter layers each being comprised of silicon. A buffer layer comprising SiₓGe₁₋ₓ and a tunnel junction are positioned between the top photovoltaic cell and the buffer layer. The III-V structure is lattice-matched or pseudomorphic to the substrate, which is a doped germanium layer in some embodiments. FIGS. 1-5 illustrate exemplary structures.

An exemplary fabrication method includes obtaining a crystalline silicon base and forming an emitter layer on the base. As discussed above, the emitter layer can be formed via implantation, diffusion or epitaxially grown. The emitter layer can be formed prior to the base in some embodiments of the method. As further discussed above, the emitter layer can alternatively be formed upon deposition of the SiGe portion of the buffer layer 64 on the base layer 60. A bottom cell is accordingly obtained by such fabrication. Silicon-based solar cells may alternatively be obtained from manufacturers or other sources. The buffer layer 64 is formed on the silicon base or emitter depending on whether the underlying silicon-based structure comprises a solar cell or only an absorption layer. The top surface of the buffer layer 64 is textured in some embodiments to improve light trapping prior to formation of the III-V top cell. The resulting structure, which comprises the bottom cell and buffer layer, is subjected to thermal desorption in the presence of phosphine or arsine gas at a temperature range of 500-680° C. to remove an oxide layer that may have formed on the buffer layer 64. The n-(In)GaAs layer 66 is formed following such oxide removal. This buffer layer can be formed in the same reactor used to form the III-V top cell. As known to those of skill in the art, III-V solar cell structures can be formed in reactors at temperatures between 500-700° C. Formation of the III-V structures disclosed herein is effected, by pseudomorphic or lattice-matched growth, using such reactors in accordance with embodiments of the method. Epitaxial methods known to those of skill in the art, including chemical vapor deposition such as MOCVD, can be employed for forming the layers of the III-V structures disclosed herein such that they are lattice-matched or pseudomorphic to the underlying (e.g. one hundred percent germanium) substrate layer.

The formation of the back surface field structures of certain exemplary tandem solar cell structures disclosed herein may take place prior to or after formation of the III-V top cells. The determination as to when such bottom contact structures should be formed is based at least in part on the materials employed and temperatures required. Referring, for example, to the structure shown in FIG. 3, various materials may be employed for forming the passivating layers of the localized back surface field structures. If a SiO₂ passivating layer is employed, such a layer is ordinarily formed by thermal oxidation in a temperature range between 800-1100° C. A SiO₂ passivating layer would accordingly be formed prior to formation of the III-V top cell. SiNₓ and a-Si:H (hydrogenated amorphous silicon) passivating layers are formed via PECVD at temperatures below those employed to form the III-V top cell and can accordingly be formed after formation of the top cell. With respect to the LBSF structure shown in FIG. 2, the p+ regions in the p-Si base and the passivating layer are formed prior to growth of the III-V top cell. The passivating layer is deposited on the base layer 60 and patterned. Following formation of the p+ regions 70, the contact layer 68 is deposited. The heterojunction a-Si:H based back surface field in the solar cell structure 400 shown in FIG. 4, comprising layers deposited via PECVD, is formed subsequent to formation of the III-V top cell. The back surface field 78 of the structure 500 shown in FIG. 5 is also formed subsequent to the formation of the top cell.

Given the discussion thus far, a multi junction solar cell structure is provided in accordance with the teachings herein. Exemplary structures 100, 200, 300 and 400 are shown in FIGS. 1-4, respectively. The top photovoltaic cell of the solar cell structure has a bandgap between 1.8-2.1 eV and includes a first base layer 38 and a first emitter layer 40 adjoining the first base layer, the first base and emitter layers each being comprised of a III-V semiconductor material. The bottom photovoltaic cell of the solar cell structure includes a second base layer 60 and a second emitter layer 62 adjoining the second base layer, the second base and emitter layers each being comprised of silicon. A buffer layer is between the top and bottom photovoltaic cells, the buffer layer comprising silicon and germanium and having a germanium-rich portion. As discussed above, layer 64 is comprised of a silicon and germanium and has a germanium-rich portion that can be up to one hundred percent germanium. The top photovoltaic cell is lattice matched or pseudomorphic to the germanium-rich portion of the buffer layer. A tunnel junction is between the top photovoltaic cell and the buffer layer, as exemplified by layers 34A and 34B. The silicon-based bottom cell has a thickness of less than 50 μm in some embodiments as the top III-V cell absorbs nearly fifty percent of the usable spectrum.

Some embodiments of the multi junction solar cell structure further comprise a first contact layer 48 in electrical communication with the top photovoltaic cell and a second contact layer 68 in electrical communication with the bottom photovoltaic cell. In some embodiments, such as shown in FIGS. 2 and 3, the second contact layer 68 contacts the second base layer of the bottom cell at a plurality of discrete areas and further include a passivating layer 72 between the second contact layer and the second base layer 60. In other embodiments, such as shown in FIG. 2, a plurality of highly doped regions 70 are provided in the second base layer 60, the highly doped regions comprising a localized back surface field structure contacting the second contact layer 68 at the plurality of discrete areas.

The multi junction solar cell structure further includes a back surface field adjoining the second base layer in some embodiments. The structures 200, 400 and 500 include back surface field structure. In some embodiments, the back surface field comprises a heterojunction. The structures 400, 500 include heterojunctions comprised of hydrogenated amorphous silicon.

The multi junction solar cell structure has a buffer layer 64 with a thickness of less than 0.5 μm in some embodiments and less than 0.25 μm in other embodiments. A surface of the buffer layer 64 is textured in some embodiments. In some embodiments, the top photovoltaic cell has a thickness of less than 1.5 μm. In one or more embodiments, the solar cell structure further includes a second buffer layer 66 between the buffer layer 64 comprising silicon and germanium and the tunnel junction 34A,B, the second buffer layer 66 being comprised of III-V semiconductor material and effective for avoiding anti-phase boundary defects. The base layer 60 of the bottom photovoltaic cell is comprised of p-type crystalline silicon in some embodiments. In some embodiments, the buffer layer 64 comprising silicon and germanium includes a SiGe portion adjoining the second emitter layer 62, and the germanium-rich portion of the buffer layer 64 comprises substantially one hundred percent germanium. In some embodiments, the first base layer 38 of the top photovoltaic cell is comprised of p-InGaP, p-InGaAlP, or p-AlGaAs. The buffer layer comprising silicon and germanium includes a germanium-rich portion comprised of at least ninety percent germanium in some embodiments, the germanium-rich portion being comprised of a substantially greater percentage of germanium than the first SiGe portion, the thickness of the germanium-rich portion of the buffer layer greatly exceeding the thickness of the first SiGe portion thereof.

A second exemplary multi junction III-V solar cell structure includes a top photovoltaic cell having a bandgap between 1.8-2.1 eV, the top photovoltaic cell including a first base layer 38 and a first emitter layer 40 adjoining the first base layer, the first base and emitter layers each being comprised of a III-V semiconductor material. A bottom photovoltaic cell thereof includes a crystalline silicon second base layer 60 and a second emitter layer 62 adjoining the second base layer. A first buffer layer 64 has a thickness of less than 0.5 μm and is located between the top and bottom photovoltaic cells. The first buffer layer includes a silicon germanium portion adjoining the bottom photovoltaic cell and a germanium-rich portion comprising at least ninety percent germanium, the top photovoltaic cell being lattice-matched or pseudomorphic to the germanium-rich portion of the first buffer layer. A tunnel junction is located between the first buffer layer and the top photovoltaic cell. A second buffer layer 66 is located between the first buffer layer and the tunnel junction 34A, 34B, the second buffer being effective for avoiding antiphase boundary defects. In one or more embodiments of the second exemplary structure, a majority of the thickness of the first buffer layer is comprised of the germanium-rich portion, the germanium-rich portion comprising substantially one hundred percent germanium, and the top photovoltaic cell is lattice-matched or pseudomorphic to germanium.

An exemplary method provided in accordance with the present disclosure includes obtaining a bottom photovoltaic structure comprising a crystalline silicon base 60 and an emitter layer comprising silicon on the base, forming a first buffer layer 64 on the bottom photovoltaic structure, the first buffer layer including a first portion comprising silicon and germanium and a second, germanium-rich portion having a substantially greater percentage of germanium than the first portion, forming a tunnel junction 34A, 34B over the first buffer layer, and forming a top photovoltaic cell over the tunnel junction and pseudomorphic or lattice matched to the germanium-rich portion of the buffer layer. The top photovoltaic cell includes a first base layer 38 and a first emitter layer 40 adjoining the first base layer, the first base and emitter layers each being comprised of a III-V semiconductor material. The top cell bandgap is between 1.8-2.1 eV. In a further exemplary embodiment of the method, the step of forming the first buffer layer further includes forming the first portion of the first buffer layer 64 as the emitter layer of the bottom photovoltaic structure. The emitter layer would accordingly contain germanium if formed in this manner. The step of forming the first buffer layer 64 includes forming the second, germanium-rich portion such that germanium comprises substantially one hundred percent of the second portion in one or more embodiments of the method, in which case the top cell would be lattice matched to germanium. The method further includes forming a second buffer layer comprised of III-V semiconductor material and effective for avoiding antiphase boundary defects in exemplary embodiments. In one or more further exemplary embodiments, the method further includes forming a bottom contact layer that contacts the crystalline silicon base of the bottom photovoltaic structure at a plurality of discrete areas. The photovoltaic cells 200, 300 schematically illustrate exemplary embodiments of contact layers formed in such a manner. In one or more further exemplary embodiments, the method, further comprises forming a plurality of highly doped regions 70 in the crystalline silicon base 60 of the bottom photovoltaic structure, the highly doped regions comprising a localized back surface field structure contacting the bottom contact layer 68 at the plurality of discrete areas. In alternative embodiments of the method, the step of forming a back surface field adjoining the second base layer is performed, wherein the back surface field comprises a heterojunction. Exemplary structures 400, 500 resulting from such a method are shown in FIGS. 4 and 5, each of which includes a heterojunction based on hydrogenated amorphous silicon. The first buffer layer 64 is formed to a thickness of less than 0.5 μm in some embodiments and less than 0.25 μm in further embodiments, as discussed above. In some embodiments, a texturing step is employed to provide a textured surface on the first buffer layer to improve light trapping.

Those skilled in the art will appreciate that the exemplary structures discussed above can be distributed in raw form or incorporated as parts of intermediate products or end products that benefit from having photovoltaic elements therein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Terms such as “above” and “below” are used to indicate relative positioning of elements or structures to each other as opposed to relative elevation.

The corresponding structures, materials, acts, and equivalents of all means or step plus function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

1.-15. (canceled)

16. A method comprising:
obtaining a bottom photovoltaic structure comprising a crystalline silicon base and an emitter layer comprising silicon on the base;
forming a first buffer layer on the bottom photovoltaic structure, the first buffer layer including a first portion comprising silicon and germanium and a second, germanium-rich portion having a substantially greater percentage of germanium than the first portion;
forming a tunnel junction over the first buffer layer, and
forming a top photovoltaic cell having a bandgap between 1.8-2.1 eV over the tunnel junction and lattice matched or pseudomorphic to the germanium-rich portion of the buffer layer, the top photovoltaic cell including a first base layer and a first emitter layer adjoining the first base layer, the first base and emitter layers each being comprised of a III-V semiconductor material.

17. The method of claim 16, wherein the step of forming the first buffer layer further includes forming the first portion of the buffer layer as the emitter layer of the bottom photovoltaic structure.

18. The method of claim 16, wherein the step of forming the first buffer layer includes forming the second, germanium-rich portion such that germanium comprises substantially one hundred percent of the second portion.

19. The method of claim 16, further including forming a second buffer layer comprised of III-V semiconductor material and effective for avoiding antiphase boundary defects, between the first buffer layer and the tunnel junction.

20. The method of claim 19, further including forming a bottom contact layer that contacts the crystalline silicon base of the bottom photovoltaic structure at a plurality of discrete areas.

21. The method of claim 20, further comprising forming a plurality of highly doped regions in the crystalline silicon base of the bottom photovoltaic structure, the highly doped regions comprising a localized back surface field structure contacting the bottom contact layer at the plurality of discrete areas.

22. The method of claim 19, further including forming a back surface field adjoining the second base layer, wherein the back surface field comprises a heterojunction.

23. The method of claim 19, wherein the first buffer layer is formed to a thickness of less than 0.5 μm.

24-25. (canceled)
